(19) United States
(12) Patent Application Publication
(10) Pub. No.: US 2026/0293102 A1
(43) Pub. Date: Sep. 24, 2026

(54) SEMICONDUCTOR DEVICE, SEMICONDUCTOR MEMORY DEVICE, AND METHOD FOR PRODUCING SEMICONDUCTOR DEVICE

(71) Applicant: Kioxia Corporation, Tokyo (JP)

(72) Inventors: Yu SAITO, Yokkaichi Mie (JP); Takahiro FUJII, Nagoya Aichi (JP); Ryuji KAMIYA, Yokkaichi Mie (JP); Kenichiro TORATANI, Fujisawa Kanagawa (JP); Masaya TODA, Yokkaichi Mie (JP); Akito HIRANO, Yokkaichi Mie (JP)

(21) Appl. No.: 19/321,871

(22) Filed: Sep. 8, 2025

(30) Foreign Application Priority Data
Mar. 21, 2025 (JP) 2025-046962

(51) Int. Cl. H10B 12/00

(52) U.S. Cl. CPC H10B 12/33; H10B 12/05

(57) ABSTRACT

A semiconductor device includes first and second upper electrodes containing indium, gallium, zinc, or tin, first and second lower electrodes, first and second oxide semiconductor channels connecting the first and second upper electrodes and the first and second lower electrodes, respectively, and extending in a first direction, first and second gate electrodes facing the first and second oxide semiconductor channels, respectively, and first and second gate insulating films. The semiconductor device also includes a first insulating film provided between the first upper electrode and the second upper electrode in the second direction, and a second insulating film provided between the first oxide semiconductor channel and the second oxide semiconductor channel in the second direction. The first insulating film has a first film density, and the second insulating film having a second film density higher than the first film density.

### CROSS-REFERENCE TO RELATED APPLICATIONS

This application is based upon and claims the benefit of priority from Japanese Patent Application No. 2025-046962, filed Mar. 21, 2025, the entire contents of which are incorporated herein by reference.

### FIELD

Embodiments described herein relate generally to a semiconductor device and a semiconductor memory device.

### BACKGROUND

There have been known semiconductor elements including electrodes made of a metal oxide including indium.

The production process of a semiconductor element may lead to a defect caused by a metal oxide including indium (In), gallium (Ga), zinc (Zn), or tin (Sn).

### BRIEF DESCRIPTION OF THE DRAWINGS

FIG. 1 is a circuit diagram of an example of a circuit configuration of a memory cell array according to a first embodiment.

FIG. 2 is a cross-sectional diagram illustrating an example of the structure of a semiconductor memory device according to the first embodiment.

FIG. 3 is a cross-sectional diagram illustrating a part of the semiconductor memory device according to the first embodiment.

FIG. 4 is a cross-sectional diagram illustrating a part of a semiconductor memory device according to a second embodiment.

FIG. 5 is a cross-sectional diagram illustrating a part of a semiconductor memory device according to a third embodiment.

FIG. 6 is a cross-sectional diagram illustrating a part of a semiconductor memory device according to a fourth embodiment.

FIGS. 7-15 are cross-sectional diagrams illustrating process steps of a production process of the semiconductor memory device according to the first embodiment.

### DETAILED DESCRIPTION

An object of the present disclosure is to provide a semiconductor device and a semiconductor memory device that are capable of reducing or eliminating a defect caused by a metal oxide including indium, gallium, zinc, or tin.

In general, according to an embodiment, a semiconductor device according to the present disclosure includes: a first upper electrode containing indium, gallium, zinc, or tin; a first lower electrode; a first oxide semiconductor channel connecting the first upper electrode and the first lower electrode and extending in a first direction; a first gate electrode facing the first oxide semiconductor channel; a first gate insulating film provided between the first oxide semiconductor channel and the first gate electrode; a second upper electrode aligned with the first upper electrode in a second direction, the second upper electrode containing indium, gallium, zinc, or tin, the second direction being perpendicular to the first direction; a second lower electrode aligned with the first lower electrode in the second direction; a second oxide semiconductor channel connecting the second upper electrode and the second lower electrode together; a second gate electrode facing the second oxide semiconductor channel; a second gate insulating film provided between the second oxide semiconductor channel and the second gate electrode; a first insulating film provided between the first upper electrode and the second upper electrode in the second direction, the first insulating film having a first film density; and a second insulating film provided between the first oxide semiconductor channel and the second oxide semiconductor channel in the second direction, the second insulating film having a second film density higher than the first film density.

A semiconductor memory device according to the present disclosure includes: the above semiconductor device; a first electrode electrically connected to the first lower electrode; a second electrode electrically connected to the second lower electrode; a third electrode facing the first electrode; a fourth electrode facing the second electrode; a first capacitor insulating film provided between the first electrode and the third electrode; and a second capacitor insulating film provided between the second electrode and the fourth electrode.

A method for producing a semiconductor device according to the present disclosure is a method for producing a semiconductor device that includes: a first upper electrode containing indium, gallium, zinc, or tin; a first lower electrode; a first oxide semiconductor channel connecting the first upper electrode and the first lower electrode together; a second upper electrode containing indium, gallium, zinc, or tin; a second lower electrode; a second oxide semiconductor channel connecting the second upper electrode and the second lower electrode together; a first insulating film provided between the first upper electrode and the second upper electrode, the first insulating film having a first film density; a second insulating film provided between the first oxide semiconductor channel and the second oxide semiconductor channel, the second insulating film having a second film density higher than the first film density; and a gate electrode separated from and facing each of the first oxide semiconductor channel and the second oxide semiconductor channel, the method including forming the second insulating film by an ALD method or a CVD method or forming the second insulating film with plasma.

Embodiments according to the present disclosure will be described below with reference to the accompanying drawings. In the drawings, the same constituent elements will be given the same reference signs wherever possible for ease of understanding the description, and redundant description thereof will be omitted.

In each drawing, an X-axis, a Y-axis, and a Z-axis may be illustrated. The X-axis, the Y-axis, and the Z-axis form a right-handed three-dimensional Cartesian coordinate system. Hereinafter, the arrow direction of the X-axis may be called a positive X-axis direction, and the opposite direction to the arrow may be called a negative X-axis direction. This holds true for the other axes. Note that a positive Z-axis direction and a negative Z-axis direction may be called “upper” and “lower”, respectively. A plane orthogonal to the X-axis, the Y-axis, or the Z-axis may be called a YZ-plane, a ZX-plane, or an XY-plane, respectively. The Z-axis direction may be called an “up-down direction”. The terms “upper”, “lower”, and “up-down direction” are merely terms each indicating a relative position relationship in each drawing and are not terms that define directions with respect to a vertical direction.

The dimensions and the like of constituent elements illustrated in the drawings may be made different from actual dimensions unless otherwise specifically stated, for ease of understanding the description.

The term “connection” herein includes not only a physical connection but also an electrical connection. The term “connection” herein includes not only a direct connection but also an indirect connection unless otherwise specified.

The phrase “formed on the upper side of something” means not only the case of being formed directly on it but also the case of being formed on the upper side of it with another thing interposed therebetween, unless otherwise specified. This holds true for the “formed on the lower side of” and the like.

### First Embodiment

A configuration of a semiconductor memory device according to a first embodiment will be described.

A semiconductor memory device 101 according to the first embodiment is an oxide-semiconductor channel transistor RAM (OCTRAM). The semiconductor memory device 101 includes a memory cell array.

### Circuit Configuration of Semiconductor Memory Device

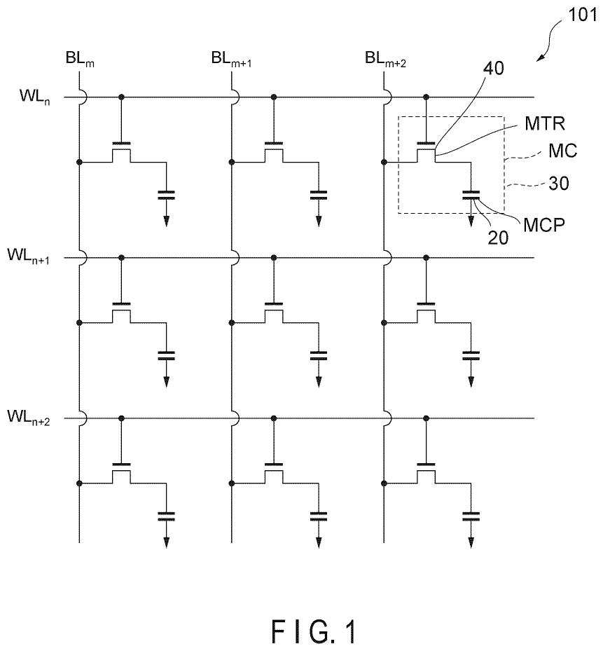

FIG. 1 illustrates an example of the circuit configuration of the semiconductor memory device 101 according to the present embodiment. As illustrated in FIG. 1, the semiconductor memory device 101 includes the memory cell array configured with a plurality of memory cells MC, a plurality of word lines WL, and a plurality of bit lines BL. In FIG. 1, a word line WLₙ, a word line WLₙ₊₁, and a word line WLₙ₊₂ (here, n is a positive integer) are illustrated as an example of the plurality of word lines WL. In addition, a bit line BLₘ, a bit line BLₘ₊₁, and a bit line BLₘ₊₂ (here, m is a positive integer) are illustrated as an example of the plurality of bit lines BL.

The plurality of memory cells MC are arranged in, for example, a matrix pattern arrangement to form the memory cell array. The memory cells MC each includes a memory transistor MTR, which is a field-effect transistor (FET), and a memory capacitor MCP.

A plurality of memory cells MC provided along a row direction are connected to one of the word lines WL (e.g., the word line WLₙ) corresponding to the row (e.g., the nth row) to which the memory cells MC belong. More in detail, the gate of the memory transistor MTR included in each memory cell MC is connected to the word line WL corresponding to the row to which the memory cell MC belongs.

A plurality of memory cells MC provided along a column direction are connected to one of the bit lines BL (e.g., the bit line BLₘ₊₂) corresponding to the column (e.g., the (m+2)th column) to which the memory cells MC belong. More in detail, one of the source or the drain of the memory transistor MTR included in each memory cell MC is connected to the bit line BL corresponding to the column to which the memory cell MC belongs. The other of the source or the drain of the memory transistor MTR is connected to one of the electrodes of the memory capacitor MCP included in the memory cell MC.

Each memory capacitor MCP is configured to retain data by holding electric charges. The memory capacitor MCP includes a capacitor dielectric film and capacitor electrodes, one of which is connected to the other of the source or the drain of the memory transistor MTR and the other of which faces the one with the capacitor dielectric film interposed therebetween.

In the configuration described above, by applying a voltage to a given word line WL, a plurality of predetermined memory transistors MTR connected to the given word line WL is switched and by feeding a current to the bit line BL connected to a memory transistor MTR in which electric charges are to be stored, the electric charges can be stored, via one memory transistor MTR connected to the given word line WL and the bit line BL, in the memory capacitor MCP connected to the memory transistor MTR. In this manner, the memory cells MC of the memory cell array are each configured to retain data.

### Physical Configuration of Semiconductor Memory Device

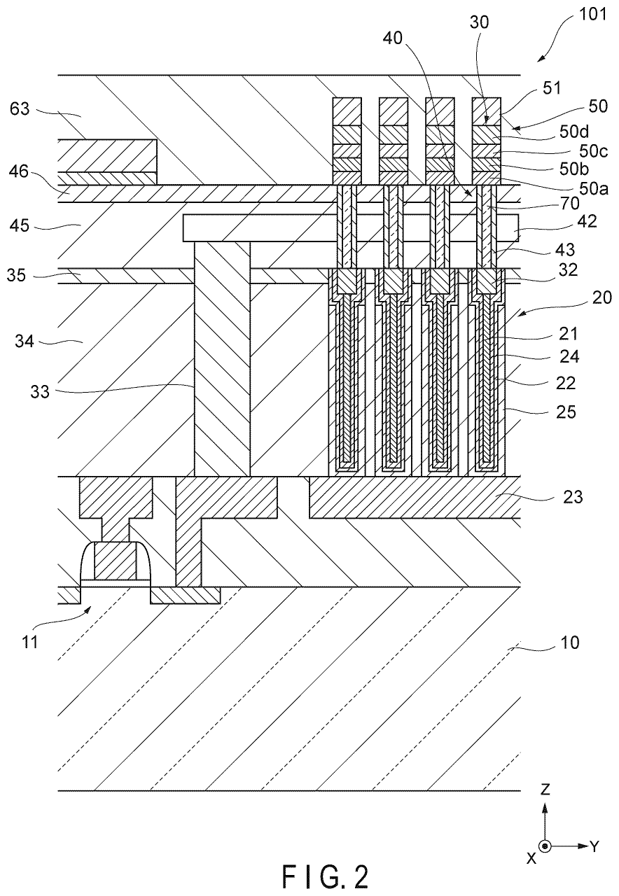

FIG. 2 is a cross-sectional diagram schematically illustrating the physical configuration of the semiconductor memory device 101 according to the present embodiment. As illustrated in FIG. 2, the semiconductor memory device 101 includes a semiconductor substrate 10, a logic circuit 11, capacitors 20, semiconductor devices 30, electric conductors 33, and insulating layers 34, 35, 45, 46, and 63.

The capacitors 20 are equivalent to the memory capacitors MCP in FIG. 1. The capacitors 20 each include an electric conductor 21, a capacitor electrode 24 electrically connected to the electric conductor 21 (an example of a “first or second electrode”), a capacitor electrode 25 facing the capacitor electrode 24 (an example of a “third or fourth electrode”), an insulating film 22 provided between the capacitor electrode 24 and the capacitor electrode 25 (an example of a “first or second capacitor insulating film”), and an electric conductor 23 electrically connected to the capacitor electrode 25 to give the capacitor electrode 25 a certain level of electric potential (e.g., a ground potential).

The electric conductor 21 includes an upper end portion that is in contact with the lower end of a lower electrode 32. The electric conductor 21 is formed in such a manner as to extend in the downward direction from the upper end portion. The capacitor electrode 24 is formed electrically connected to the lower electrode 32 and the electric conductor 21. In the present embodiment, the capacitor electrode 24 is formed covering the lateral surface of the lower electrode 32 and the lateral surface of the electric conductor 21. The insulating film 22 is formed covering the lateral surface of the capacitor electrode 24. The capacitor electrode 25 wraps around a lower lateral surface and the bottom surface of insulating film 22. The capacitor electrode 25 includes a lower end that is in contact with the upper end surface of the electric conductor 23.

The electric conductor 21 may be made of a material such as amorphous silicon. The insulating film 22 may be made of a material such as hafnium oxide. The electric conductor 23 and the capacitor electrodes 24 and 25 may each be made of a material such as tungsten (W) or titanium nitride (TiN).

The capacitors 20 according to the present embodiment are pillar capacitors that extend in the up-down direction. Field-effect transistors 40 included in the semiconductor devices 30 according to the present embodiment are longitudinal transistors with channels extending in the up-down direction, as will be described below. As illustrated in FIG. 2, the capacitors 20 are formed on the lower sides of the field-effect transistors 40.

For example, in the embodiment illustrated in FIG. 2, a virtual straight line including the central axis of each capacitor 20 extending in the up-down direction penetrates the channel of the corresponding field-effect transistor 40 extending in the up-down direction. It is thus possible to increase the density of the memory cell array.

The semiconductor memory device 101 in the present embodiment is provided with at least part of the logic circuit 11 below the capacitors 20, and it is thus possible to achieve further integration of the semiconductor memory device, as will be described below. It is noted that, in place of the three-dimensional capacitors described in the present embodiment, the semiconductor memory device 101 may be provided with capacitors of another type having a configuration that enables the storage of electric charges.

The semiconductor devices 30 each include the field-effect transistor 40 equivalent to the memory transistor MTR in FIG. 1, the lower electrode 32 (an example of a “first or second lower electrode”), an upper electrode 50 (an example of a “first or second upper electrode”), and a conductive layer 51.

The field-effect transistors 40 each include an oxide semiconductor layer 70 (an example of a “first or second oxide semiconductor channel”) that is electrically connected to the lower electrode 32, is formed on the upper side of the lower electrode 32, and is equivalent to the channel of the field-effect transistor 40, an insulating film 43 (an example of a “first or second gate insulating film”) wrapping around the lateral surface of the oxide semiconductor layer 70, and a conductive layer 42 (an example of a “first or second gate electrode”) provided facing the oxide semiconductor layer 70 with the insulating film 43 interposed therebetween.

The upper electrode 50 is electrically connected to the oxide semiconductor layer 70 and is formed on the upper side of the oxide semiconductor layer 70. In the present embodiment, the semiconductor devices 30 are each formed on the upper side of the corresponding capacitor 20.

The lower electrode 32 is provided such that its upper end is in contact with the lower end of the oxide semiconductor layer 70, and that its lower end is in contact with the electric conductor 21 of the capacitor 20. Thus, the lower electrode 32 supplies electric charge to the capacitor 20. The lower electrode 32 is constituted by, for example, an ITO layer containing a metal oxide, such as indium tin oxide (ITO).

The oxide semiconductor layer 70 includes an upper end portion that is equivalent to one of the drain or the source of the field-effect transistor 40, a lower end portion that is equivalent to the other of the drain or the source, and a center portion that is provided between the upper end portion and the lower end portion and is equivalent to the channel. The oxide semiconductor layer 70 is formed in a columnar body extending in the up-down direction. Therefore, each of the field-effect transistors 40 is what is called a longitudinal transistor.

The oxide semiconductor layer 70 is a semiconductor in which oxygen vacancy serves as a doner. The oxide semiconductor layer 70 includes indium (In), zinc (Zn), and gallium (Ga). More in detail, the oxide semiconductor layer 70 includes an oxide of indium, gallium, and zinc, that is, IGZO (InGaZnO). The oxide semiconductor layer 70 has, for example, an amorphous structure. Note that the oxide semiconductor layer 70 may be another type of oxide semiconductor.

The insulating film 43 is made of, for example, a silicon nitride film (Si₃N₄), which contains silicon and nitrogen.

The conductive layer 42 is equivalent to the gate electrode of the field-effect transistor 40. The conductive layer 42 is provided facing the center portion of the oxide semiconductor layer 70 between the upper end and the lower end of the oxide semiconductor layer 70 with the insulating film 43 interposed therebetween. The conductive layer 42 is made of, for example, tungsten (W).

The upper electrode 50 includes a metal oxide layer 50a, an intermediate conductive layer 50b, a barrier metal layer 50c, and a metal film 50d.

The upper electrode 50 is provided on the upper side of the oxide semiconductor layer 70, being in contact with the upper end of the oxide semiconductor layer 70. The metal oxide layer 50a in the upper electrode 50 is made of a metal oxide containing oxygen, indium, and tin. Specifically, the metal oxide layer 50a forms an electrode made of the indium tin oxide (ITO) (an ITO electrode). The metal oxide layer 50 a has a thickness of, for example, 1 to 10 nm.

In semiconductor memory device 101 in the present embodiment, the configuration in which the metal oxide layer 50a (ITO) and the oxide semiconductor layer 70 (IGZO), which result in a good work function matching, are brought into contact with each other at the upper end of the oxide semiconductor layer 70. Thus, the resistance between the metal oxide layer 50a and the oxide semiconductor layer 70 can be decreased.

The intermediate conductive layer 50b is electrically connected to the metal oxide layer 50a. The intermediate conductive layer 50b is formed on the upper side of the metal oxide layer 50a, being in contact with the metal oxide layer 50a. The intermediate conductive layer 50b contains oxygen and a first metal that is contained in the barrier metal layer 50c.

In the present embodiment, the intermediate conductive layer 50b is made of an oxide of titanium (Ti), in other words, titanium oxide (TiO). The intermediate conductive layer 50b has a thickness of, for example, 1 to 10 nm.

The barrier metal layer 50c is electrically connected to the intermediate conductive layer 50b. The barrier metal layer 50c is formed on the upper side of the intermediate conductive layer 50b, being in contact with the intermediate conductive layer 50b. The barrier metal layer 50c contains the first metal that is contained in the intermediate conductive layer 50b.

In the present embodiment, the barrier metal layer 50c is made of a barrier metal, for example, titanium nitride (TiN). The barrier metal layer 50c has a thickness of, for example, 1 to 10 nm.

The metal film 50d is electrically connected to the barrier metal layer 50c. The metal film 50d is formed on the upper side of the barrier metal layer 50c. The metal film 50d is made of tungsten (W). The metal film 50 d has a thickness of, for example, 10 to 50 nm.

Here, the formation of the metal film 50d typically requires a high temperature of 300° C. or higher. For example, the formation of a tungsten film requires a temperature of 350° C. or higher. However, if the barrier metal layer 50c is directly stacked on the metal oxide layer 50a in the upper electrode 50, the high temperature for the formation of the metal film 50d can break the bond between indium and oxygen in the metal oxide layer 50a, causing oxygen in the metal oxide layer 50a to diffuse into the barrier metal layer 50c in the vicinity of the interface between the metal oxide layer 50a and the barrier metal layer 50c, resulting in a decrease in oxygen ratio, which deteriorates the adhesiveness of the interface to cause a separation.

In contrast, the upper electrode 50 of the semiconductor memory device 101 according to the present embodiment includes, between the metal oxide layer 50a and the barrier metal layer 50c, the intermediate conductive layer 50b containing oxygen and the same metal (e.g., titanium) as the metal contained in the barrier metal layer 50c.

With such a configuration, the metal (e.g., titanium) in the intermediate conductive layer 50b is oxidized, yielding an abundance of oxygen. Thus, the metal (e.g., titanium) in the intermediate conductive layer 50b is inhibited from extracting the oxygen in the metal oxide layer 50a.

As a result, the decrease in oxygen ratio in the metal oxide layer 50a is reduced or eliminated at the vicinity of the interface between the metal oxide layer 50a and the intermediate conductive layer 50b. In the metal oxide layer 50a, this makes it possible for oxygen in the vicinity of the interface with the intermediate conductive layer 50b to be bonded to indium contained in the metal oxide layer 50a and to be bonded to the metal (e.g., titanium) contained in the intermediate conductive layer 50b.

As a result, even when the metal film 50d is formed at the high temperature, it is possible to inhibit the bond between indium and oxygen in the metal oxide layer 50a from being broken to cause the oxygen to diffuse into the barrier metal layer 50c, accelerating the separation. In addition, since the intermediate conductive layer 50b and the barrier metal layer 50c contain the same metal, it is also possible to inhibit the separation between the intermediate conductive layer 50b and the barrier metal layer 50c.

The upper electrode 50 electrically connects the conductive layer 51, which is equivalent to one of the bit lines BL (FIG. 1) and the field-effect transistor 40 together. For example, the conductive layer 51 is provided in the upper portion of the upper electrode 50, being in contact with the metal film 50d, which is at the upper end of the upper electrode 50.

The logic circuit 11 includes peripheral circuits such as a decoder for selecting one or more memory cells MC from among the plurality of memory cells MC included in the semiconductor memory device 101, a sense amplifier connected to the bit lines BL, and registers implemented with an SRAM.

The logic circuit 11 may be implemented with CMOS circuits, each of which includes field-effect transistors including a P-channel field-effect transistor (Pch-FET) and an N-channel field-effect transistor (Nch-FET), which are formed by a CMOS process.

The field-effect transistors of the logic circuit 11 can be formed on the semiconductor substrate 10, such as a monocrystalline silicon substrate. Each of the Pch-FET and the Nch-FET is what is called a lateral (planar) field-effect transistor, which has a channel region, a source region, and a drain region on the semiconductor substrate 10 and has, in a region close to the surface of the semiconductor substrate 10, a channel for transporting charge carriers in the X-axis direction or the Y-axis direction, which is substantially parallel to the surface of the semiconductor substrate 10. FIG. 2 illustrates an example of a lateral field-effect transistor included in this logic circuit 11.

The electric conductors 33 include wires that electrically connect the logic circuit 11 and the semiconductor devices 30. The electric conductors 33 may each include a via wire extending in the up-down direction and a wire extending in a right-left direction. For example, as illustrated in FIG. 2, the electric conductors 33 may each include a via wire that extends in the Z-axis direction and connects one of the word lines WL and the logic circuit 11 provided on the semiconductor substrate 10. The electric conductors 33 may each be made of, for example, copper.

The insulating layer 34 is formed between the capacitors 20 in such a manner as to insulate the capacitors 20. The insulating layer 35 is provided on the upper side of the insulating layer 34. The insulating layer 45 (an example of a “second insulating film” and a “fourth insulating film”) is formed between the oxide semiconductor layers 70 in such a manner as to insulate the oxide semiconductor layers 70. The insulating layer 63 (an example of a “first insulating film”) is formed between the upper electrodes 50, between the conductive layers 51, and on the upper sides of the conductive layers 51 in such a manner as to insulate the upper electrodes 50 and insulate the conductive layers 51. The insulating layer 46 (an example of a “high-density part” and a “second insulating film”) is formed as a part of the insulating layer 45 or on a surface region of the insulating layer 45 in the present embodiment, and is in contact with the insulating layer 63.

The insulating layer 34, the insulating layer 45, and the insulating layer 46 are each made of, for example, a silicon oxide film, which contains silicon and oxygen. The insulating layer 35 is made of, for example, a silicon nitride film, which contains silicon and nitrogen, so as to function as a protective layer. The insulating layer 63 is made of, for example, a silane film, which contains silicon and hydrogen. The insulating layer 63 has a first film density, the insulating layer 46 has a second film density, and the second film density is greater than the first film density.

In the semiconductor memory device 101 having the configuration described above, in writing data, by applying a voltage to a word line WL selected by the logic circuit 11 to make the field-effect transistor 40 connected to the word line WL conductive and by applying a voltage to a bit line BL selected by the logic circuit 11, electric charges can be stored from the bit line BL in the corresponding memory capacitor MCP via the channel of the field-effect transistor 40, and the data is thereby stored. In reading information, the data can be read based on sensing a voltage of a bit line BL selected by the logic circuit 11 that varies in accordance with the presence or absence of electric charges stored in the corresponding memory capacitor MCP when a voltage is applied to a word line WL selected by the logic circuit 11 to make the field-effect transistor 40 connected to the word line WL conductive.

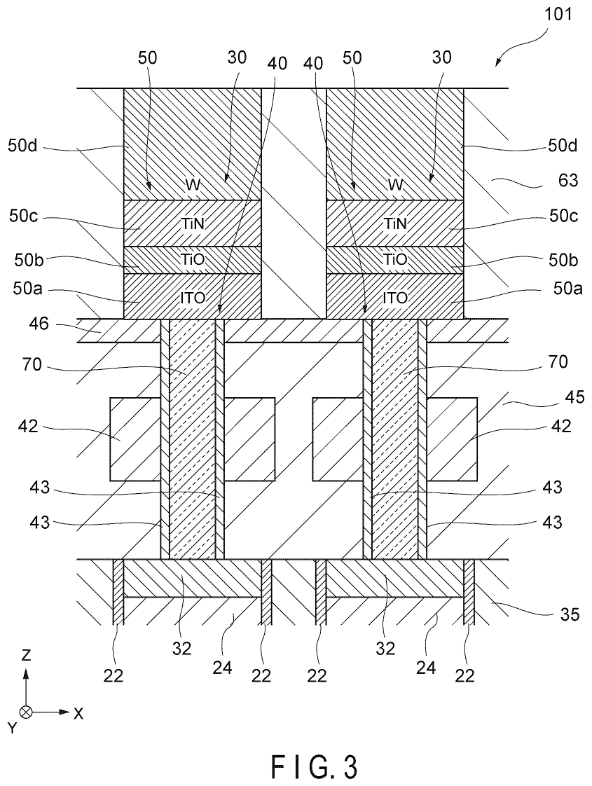

FIG. 3 illustrates an enlarged view of a part of the semiconductor memory device 101 according to the first embodiment. FIG. 3 is equivalent to a cross-sectional view taken by cutting the semiconductor memory device along a plane that is parallel to the ZX-plane, which is perpendicular to the direction in which the conductive layer 42 extends.

The inventor(s) of the present disclosure found that, in the case where the upper electrodes 50 contain indium as with the semiconductor memory device 101 according to the present embodiment, when reactive ion etching (RIE) is performed to pattern the upper electrodes 50, indium diffusing into an etching atmosphere diffuses into the surface regions of the insulating layer provided between adjacent oxide semiconductor layers 70 to form indium residues, which may short-circuit adjacent upper electrodes 50. The same problem also occurs in the case where the upper electrodes 50 contain gallium, zinc, or tin. However, the following description will be given of an example in which the upper electrodes 50 contain indium.

In order to remove the indium residues, the surface regions of the insulating layer need to be subjected to etch back for the removal. However, in the etch back, mask layers (hard mask layers 80 described later) used for the etching remain on the upper electrodes 50, making the structure from the surface of the insulating layer subjected to the etch back to the upper surfaces of the mask layers on the upper electrodes 50 have a high aspect-ratio. This incurs the risk that the structure may collapse during its production process. In addition, this requires the step of removing the indium residues, increasing the number of steps.

The semiconductor memory device 101 according to the present embodiment is provided with the insulating layer 46, which is provided between the oxide semiconductor layers 70, as an insulating layer having a film density that is increased to the extent that inhibits the diffusion of indium. Even in the case where the upper electrodes 50 contain indium, this makes it possible to inhibit the diffusion of indium into the surface regions of the insulating layer provided between adjacent oxide semiconductor layers 70. Thus, there is no need to perform the step of removing the indium residues.

Here, for a field-effect transistor including an oxide semiconductor as its channel, it is necessary to supply oxygen to the oxide semiconductor in its production process to adjust the threshold voltage of the semiconductor. However, the higher the film density of an insulating layer is, the less oxygen passes through the insulating layer. For this reason, in the semiconductor memory device 101 according to the present embodiment, only the film density of the insulating layer 46, which is involved in the occurrence of the indium residues, is increased, and the film density of the insulating layer 63, which is provided between adjacent upper electrodes 50, is made lower than the film density of the insulating layer 46, rather than making all the insulating layers high-density. With this, when oxygen annealing is performed by heating to supply oxygen to the oxide semiconductor layers 70 in a step after the insulating layer 63 is formed, the oxide semiconductor layers 70 are supplied with the oxygen through the surface of the insulating layer 63 via the insulating layer 63 and the upper electrodes 50.

### Second Embodiment

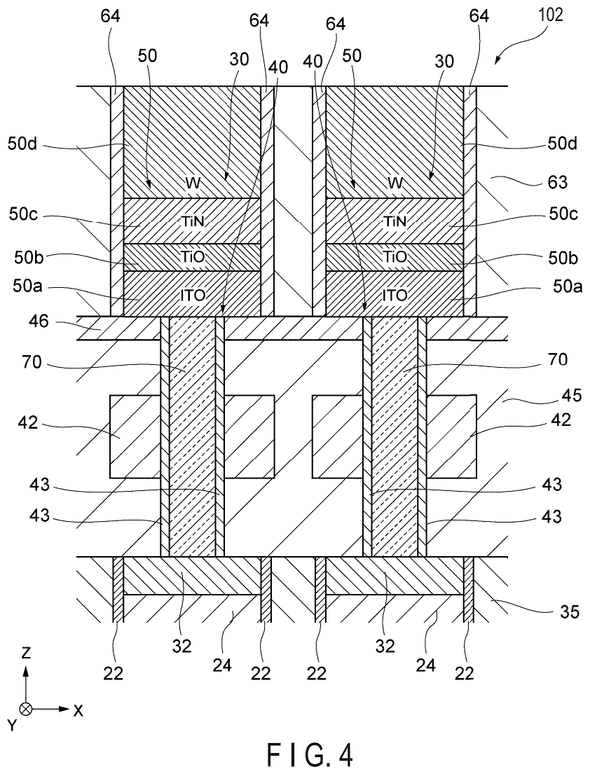

FIG. 4 illustrates a cross-sectional view of a semiconductor memory device according to a second embodiment, which is a modification of the semiconductor memory device 101 according to the first embodiment illustrated in FIG. 3.

As illustrated in FIG. 4, in a semiconductor memory device 102 according to the second embodiment, liner films each configured with an insulating layer 64 (an example of a “third insulating film”), which has a higher film density than the insulating layer 63, are provided between the upper electrodes 50 and the insulating layer 63 in the structure in the first embodiment, covering the side walls of the upper electrodes 50.

As mentioned above, the higher the film density of an insulating layer is, the less oxygen passes through the insulating layer. However, even in the case of a high-density insulating layer, it is possible to cause oxygen in an amount necessary to adjust the threshold voltage of an oxide semiconductor to pass the insulating layer as long as the insulating layer has a film thickness to some extent. The insulating layer 64 has a thickness of, for example, 5 to 10 nm. With this, when the oxygen annealing is performed by heating to supply oxygen to the oxide semiconductor layers 70 in a step after the insulating layer 63 is formed, the oxide semiconductor layers 70 are supplied with the oxygen through the surface of the insulating layer 63 via the insulating layer 63, the insulating layers 64, and the upper electrodes 50.

### Third Embodiment

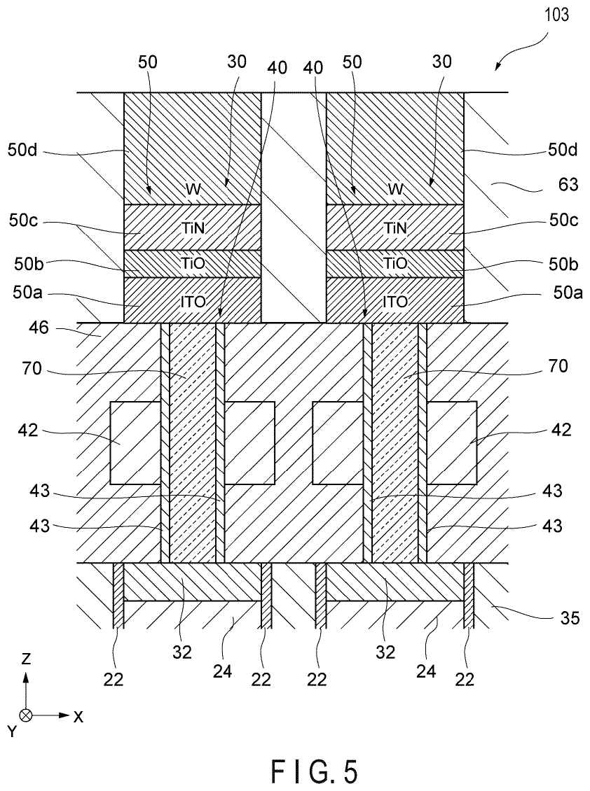

FIG. 5 illustrates a cross-sectional view of a semiconductor memory device according to a third embodiment, which is another modification of the semiconductor memory device 101 according to the first embodiment illustrated in FIG. 3.

As illustrated in FIG. 5, a semiconductor memory device 103 in the third embodiment is configured such that the insulating layer 46 alone serves as both the insulating layer 45 and the insulating layer 46 in the structure in the first embodiment. That is, in the semiconductor memory device 101 in the first embodiment, the insulating layer provided between the adjacent oxide semiconductor layers 70 is configured with, for example, the insulating layer 46 and the insulating layer 45, which has a lower film density than the insulating layer 46, so that the insulating layer is provided partly with a high-density part. In contrast, as with the semiconductor memory device 103 in the third embodiment, the entire insulating layer provided between the adjacent oxide semiconductor layers 70 may be configured with the insulating layer 46, which is a high-density part.

Even with this configuration, when the oxygen annealing is performed by heating to supply oxygen to the oxide semiconductor layers 70 in a step after the insulating layer 63 is formed, the oxide semiconductor layers 70 can be supplied with the oxygen through the surface of the insulating layer 63, which has a relatively low film density, via the insulating layer 63 and the upper electrodes 50, as in the first embodiment.

### Fourth Embodiment

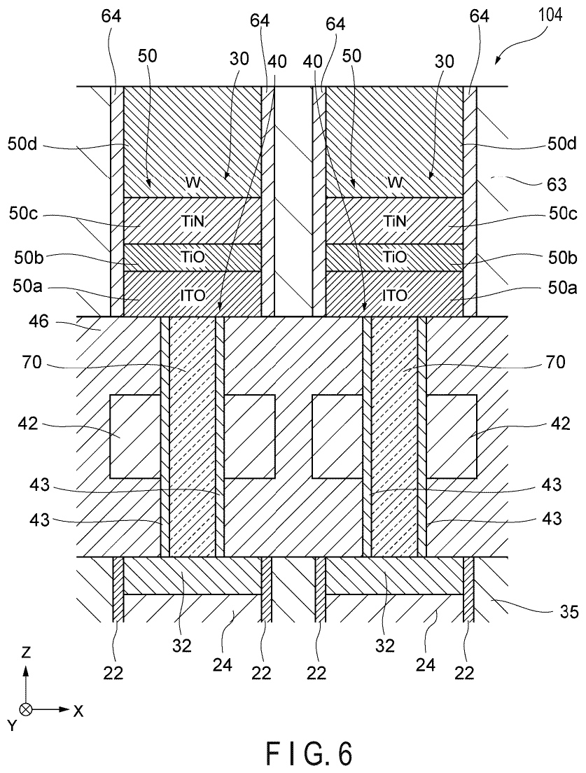

FIG. 6 illustrates a cross-sectional view of a semiconductor memory device according to a fourth embodiment, which is a modification of the semiconductor memory device 103 according to the third embodiment illustrated in FIG. 5.

As illustrated in FIG. 6, in a semiconductor memory device 104 in the fourth embodiment, liner films each configured with an insulating layer 64, which has a higher film density than the insulating layer 63, are provided between the upper electrodes 50 and the insulating layer 63 in the structure in the third embodiment, covering the side walls of the upper electrodes 50. The insulating layer 64 has a thickness of, for example, 5 to 10 nm.

Even with this configuration, when the oxygen annealing is performed by heating to supply oxygen to the oxide semiconductor layers 70 in a step after the insulating layer 63 is formed, the oxide semiconductor layers 70 can be supplied with the oxygen through the surface of the insulating layer 63 via the insulating layer 63, the insulating layers 64, and the upper electrodes 50, as in the second embodiment.

### Method for Producing Semiconductor Memory Device

As an example of a method for producing the semiconductor memory device according to the first embodiment, a method for producing the semiconductor memory device 101 will be described below.

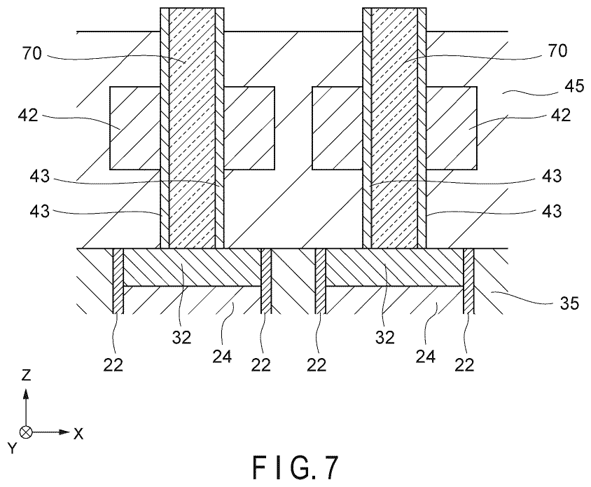

First, as illustrated in FIG. 7, the insulating layer 45 is formed such that the oxide semiconductor layers 70 are embedded in the insulating layer 45 up to an intermediate position in their height direction.

It is noted that FIG. 7 and subsequent drawings are equivalent to a cross-sectional view taken by cutting the semiconductor memory device along a plane that is parallel to the ZX-plane, which is perpendicular to the direction in which the conductive layer 42 extends.

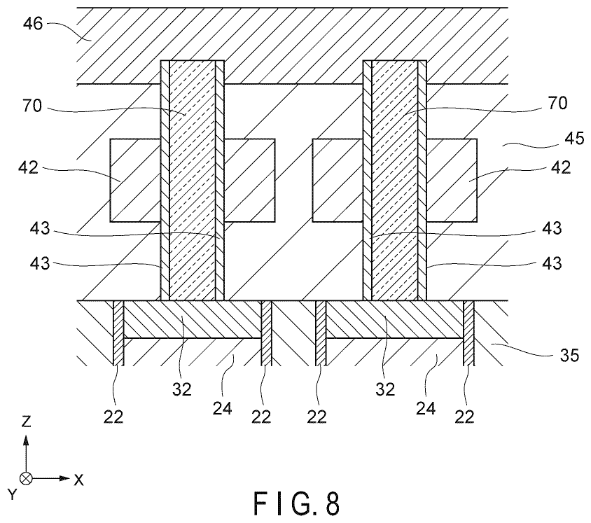

Next, as illustrated in FIG. 8, the insulating layer 46, which has a high film density, is formed on the upper side of the insulating layer 45. In order to increase the film density of the insulating layer 46, the insulating layer 46 is formed as a silicon oxide film by an atomic layer deposition (ALD) method with enhanced oxidizing power. Specifically, it is only required to prolong the duration of supplying oxidation gas. In the present embodiment, the duration of supplying the oxidation gas is set to be around 10 seconds. The insulating layer 46 may be formed by a chemical vapor deposition (CVD) method.

In order to increase the film density of the insulating layer 46, plasma modification may be performed, after the silicon oxide film is formed, on the silicon oxide film while applying an RF power of about 1000 W to about 4000 W. For example, the silicon oxide film may be densified with He plasma. In the semiconductor memory device 101 in the present embodiment, the metal oxide layer 50a is heat-sensitive. However, employing the plasma modification enables the silicon oxide film to be made high-density at a temperature of, for example, around 300° C., without excessively increasing the processing temperature.

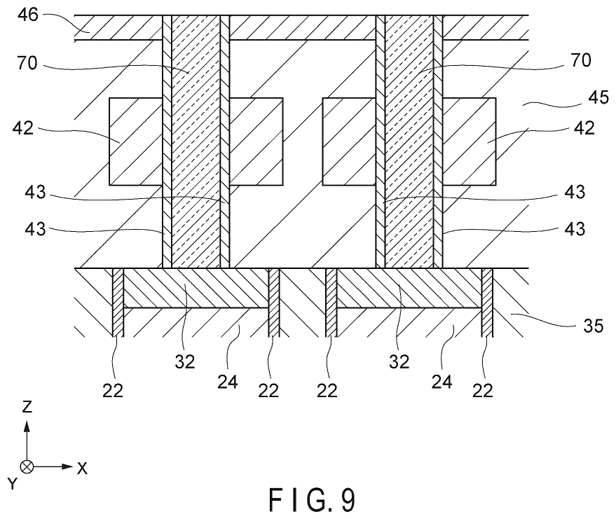

Next, as illustrated in FIG. 9, the insulating layer 46 is removed by the etch back by the reactive ion etching (RIE) or chemical mechanical polishing (CMP) until the upper end portions of the oxide semiconductor layers 70 are exposed.

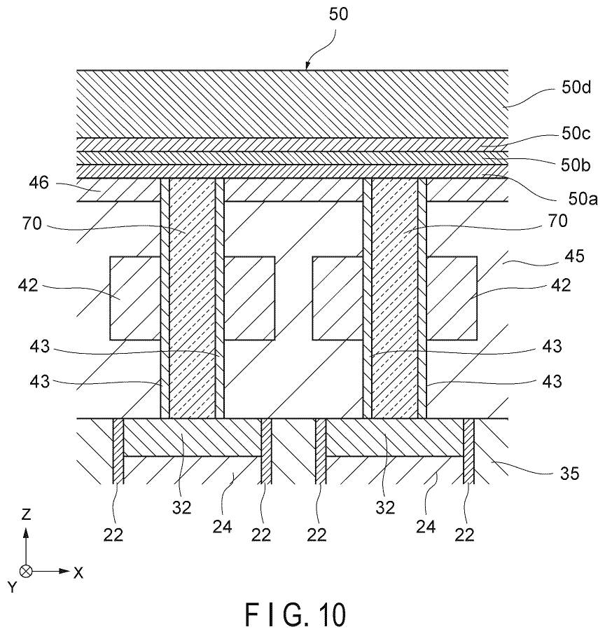

Next, as illustrated in FIG. 10, on the upper side of the insulating layer 46, the metal oxide layer 50a, the intermediate conductive layer 50b, the barrier metal layer 50c, and the metal film 50d, which are to constitute the upper electrodes 50, are formed in this order.

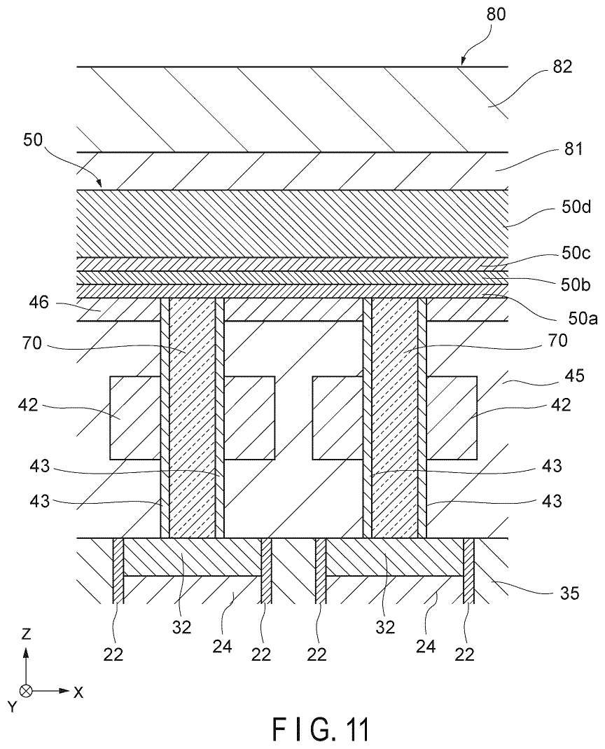

Next, as illustrated in FIG. 11, on the upper side of the metal film 50d, the hard mask layer 80 constituted by a lower hard mask layer 81 and an upper hard mask layer 82 is formed. At this time, the film density of the upper hard mask layer 82 may be made higher than the film density of the lower hard mask layer 81. For example, the lower hard mask layer 81 is formed in the form of a tetraethyl orthosilicate (TEOS) oxide film, and the upper hard mask layer 82 is formed by the atomic layer deposition (ALD) method or the chemical vapor deposition (CVD) method. In this manner, the indium residues adhere to the surface of the hard mask layer 80 in a step of etching the upper electrodes 50 described later, and it is possible to inhibit the diffusion of the indium into an atmosphere in a step of etching the hard mask layer 80.

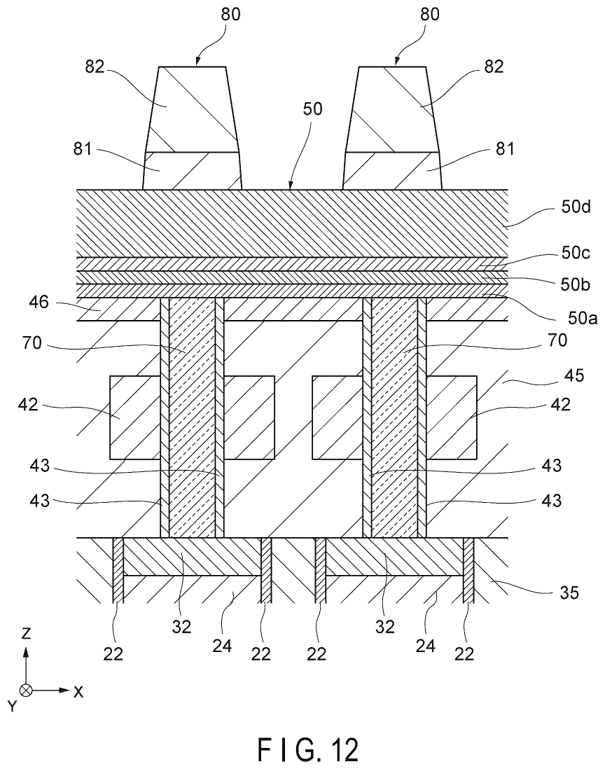

Next, as illustrated in FIG. 12, the hard mask layers 80 are patterned by the reactive ion etching (RIE) using a resist layer (not illustrated) that is formed by a photolithography method.

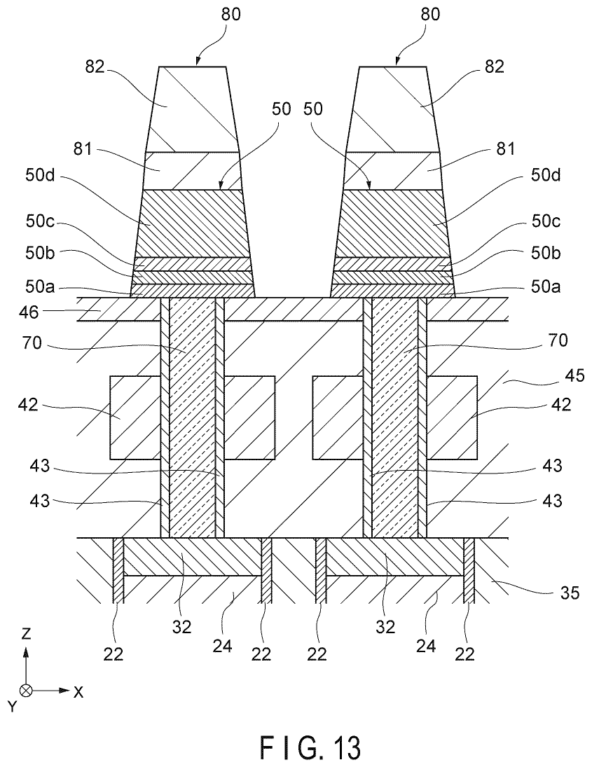

Next, as illustrated in FIG. 13, by the reactive ion etching (RIE) with the patterned hard mask layers 80 used as a mask, the metal oxide layer 50a, the intermediate conductive layer 50b, the barrier metal layer 50c, and the metal film 50d that are exposed through the hard mask layers 80 are removed. At this time, the indium included in the metal oxide layer 50a diffuses. However, the insulating layer 46 having a high film density and formed on the upper surface of the insulating layer 45 inhibits the diffusion of the indium into the insulating layer, that is, the occurrence of the indium residues.

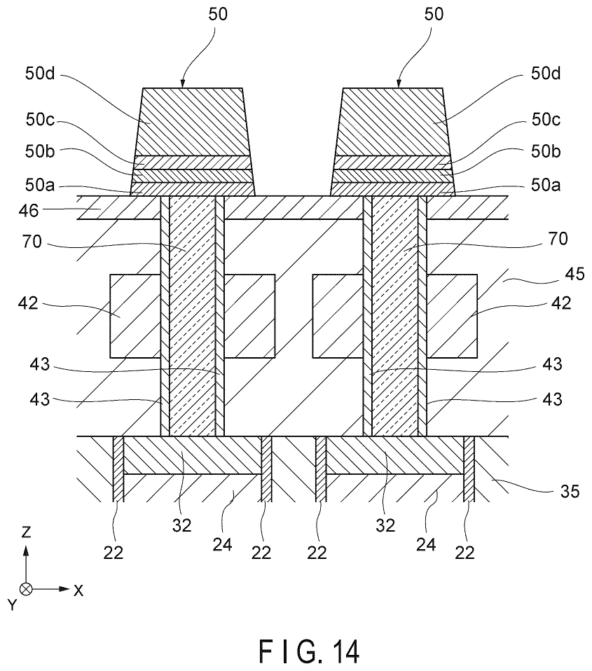

Next, as illustrated in FIG. 14, the hard mask layer 80 is removed, and thus the upper electrodes 50 are obtained.

Next, the insulating layer 63, which has a lower film density than the insulating layer 46, is formed in the form of, for example, a TEOS oxide film in such a manner as to fill the gaps between adjacent upper electrodes 50 with the insulating layer 63.

In the above-described manner, the semiconductor memory device according to the first embodiment is produced.

Here, in order to produce the semiconductor memory device according to the third embodiment, it is only required to form only the insulating layer 46, which has a high film density, as the insulating layer in which the oxide semiconductor layers 70 are embedded, in place of the steps illustrated in FIG. 7 and FIG. 8.

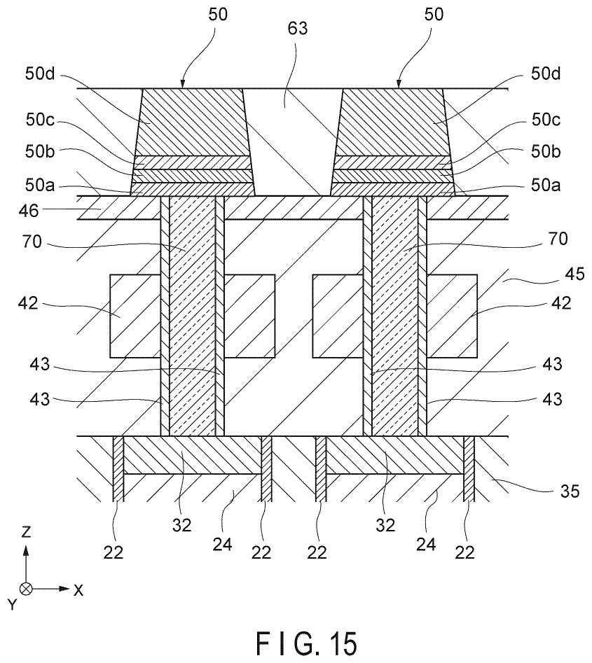

In order to produce the semiconductor memory device according to the second embodiment or the fourth embodiment, a step of forming the insulating layers 64, which have a higher film density than the insulating layer 63, on the side walls of the upper electrodes 50, as the liner films, is performed between the step illustrated in FIG. 14 and the step illustrated in FIG. 15, by the same method for forming the insulating layer 46, which has a high film density. Thereafter, the insulating layer 63 is to be formed in such a manner as to fill the gaps between adjacent upper electrodes 50 with the insulating layer 63.

The embodiments according to the present disclosure have been described above with reference to the specific examples. However, the present disclosure is not limited to these specific examples. Modifications in which these specific examples are modified as appropriate by those skilled in the art are also encompassed by the scope of the present disclosure as long as they are provided with the features of the present disclosure. Each element included in each of the specific examples mentioned above and the arrangement, condition, shape, and the like thereof are not limited to those exemplified and can be changed as appropriate. The elements included in each of the specific examples mentioned above can be combined in various manners as appropriate, provided that no technical inconsistency arises.

What is claimed is

1. A semiconductor device comprising:
a first upper electrode containing indium, gallium, zinc, or tin;
a first lower electrode;
a first oxide semiconductor channel connecting the first upper electrode and the first lower electrode and extending in a first direction;
a first gate electrode facing the first oxide semiconductor channel;
a first gate insulating film provided between the first oxide semiconductor channel and the first gate electrode;
a second upper electrode aligned with the first upper electrode in a second direction, the second upper electrode containing indium, gallium, zinc, or tin, the second direction being perpendicular to the first direction;
a second lower electrode aligned with the first lower electrode in the second direction;
a second oxide semiconductor channel connecting the second upper electrode and the second lower electrode together;
a second gate electrode facing the second oxide semiconductor channel;
a second gate insulating film provided between the second oxide semiconductor channel and the second gate electrode;
a first insulating film provided between the first upper electrode and the second upper electrode in the second direction, the first insulating film having a first film density; and
a second insulating film provided between the first oxide semiconductor channel and the second oxide semiconductor channel in the second direction, the second insulating film having a second film density higher than the first film density.

2. The semiconductor device according to claim 1, wherein the first insulating film and the second insulating film are in contact with each other.

3. The semiconductor device according to claim 1, wherein a thickness of the first insulating film in the first direction is greater than a thickness of the second insulating film in the first direction.

4. The semiconductor device according to claim 1, wherein the second insulating film is provided between the first gate insulating film and the second gate insulating film in the second direction.

5. The semiconductor device according to claim 1, wherein the first upper electrode comprises a laminate of layers including, in order: i) a first conductive layer containing indium, tin, and oxygen; ii) a second conductive layer containing a metal element; iii) a third conductive layer containing the metal element; and iv) a fourth conductive layer containing tungsten.

6. The semiconductor device according to claim 5, wherein the first conductive layer is in contact with the first insulating film, the first oxide semiconductor channel, the first gate insulating film, and the second insulating film.

7. The semiconductor device according to claim 5, wherein a thickness of the second insulating film in the first direction is less than a thickness of the first conductive layer in the first direction.

8. The semiconductor device according to claim 1, wherein the first insulating film is formed with silane and the second insulating film is formed with silicon oxide.

9. The semiconductor device according to claim 1, wherein the first insulating film is in contact with a side surface of the first upper electrode in the second direction and in contact with a side surface of the second upper electrode in the second direction.

10. The semiconductor device according to claim 1, further comprising:
a third insulating film provided between the first upper electrode and the first insulating film, the third insulation film having a third film density higher than the first film density.

11. The semiconductor device according to claim 10, wherein the third insulation film surrounds a side surface of the first upper electrode.

12. The semiconductor device according to claim 10, wherein a length of the third insulating film between the first upper electrode and the second upper electrode in the second direction is less than a length of the first insulating film between the first upper electrode and the second upper electrode in the second direction.

13. The semiconductor device according to claim 1, further comprising:
a fourth insulating film provided between the second insulating film and the first lower electrode in the first direction and between the second insulating film and the second lower electrode in the first direction, the fourth insulating film having a fourth film density lower than the second film density.

14. The semiconductor device according to claim 13, wherein a thickness of the second insulating film in the first direction is less than a thickness of the fourth insulating film in the first direction.

15. The semiconductor device according to claim 1, wherein the second insulating film is provided between the first gate insulating film and the second gate insulating film in the second direction and between the first gate electrode and the second gate electrode in the second direction.

16. The semiconductor device according to claim 1, wherein an upper surface of the second insulating film is in contact with the first upper electrode and the second upper electrode, and a lower surface of the second insulating film is in contact with the first lower electrode and the second lower electrode.

17. A semiconductor memory device comprising:
the semiconductor device according to claim 1;
a first electrode electrically connected to the first lower electrode;
a second electrode electrically connected to the second lower electrode;
a third electrode facing the first electrode;
a fourth electrode facing the second electrode;
a first capacitor insulating film provided between the first electrode and the third electrode; and
a second capacitor insulating film provided between the second electrode and the fourth electrode.

18. A semiconductor device comprising:
a first upper electrode containing indium, gallium, zinc, or tin;
a first lower electrode;
a first oxide semiconductor channel connecting the first upper electrode and the first lower electrode and extending in a first direction;
a first gate electrode facing the first oxide semiconductor channel;
a first gate insulating film provided between the first oxide semiconductor channel and the first gate electrode;
a second upper electrode aligned with the first upper electrode in a second direction, the second upper electrode containing indium, gallium, zinc, or tin, the second direction being perpendicular to the first direction;
a second lower electrode aligned with the first lower electrode in the second direction;
a second oxide semiconductor channel connecting the second upper electrode and the second lower electrode together;
a second gate electrode facing the second oxide semiconductor channel;
a second gate insulating film provided between the second oxide semiconductor channel and the second gate electrode;
a first insulating film provided between the first upper electrode and the second upper electrode in the second direction, the first insulating film having a first film density; and
a second insulating film provided between the first oxide semiconductor channel and the second oxide semiconductor channel in the second direction, the second insulating film including a high density part that has a second film density higher than the first film density.

19. A method for producing a semiconductor device that includes:
a first upper electrode containing indium, gallium, zinc, or tin;
a first lower electrode;
a first oxide semiconductor channel connecting the first upper electrode and the first lower electrode together;
a second upper electrode containing indium, gallium, zinc, or tin;
a second lower electrode;
a second oxide semiconductor channel connecting the second upper electrode and the second lower electrode together;
a first insulating film provided between the first upper electrode and the second upper electrode, the first insulating film having a first film density;
a second insulating film provided between the first oxide semiconductor channel and the second oxide semiconductor channel, the second insulating film having a second film density higher than the first film density; and
a gate electrode separated from and facing each of the first oxide semiconductor channel and the second oxide semiconductor channel, the method comprising:
forming the second insulating film by an atomic layer deposition (ALD) method or a chemical vapor deposition (CVD) method, or forming the second insulating film with plasma; and
forming, after forming the second insulating film, the first upper electrode and the second upper electrode by etching a film including indium, gallium, zinc, or tin.

20. The method according to claim 19, wherein
a hard mask layer is used for forming the first upper electrode and the second upper electrode by the etching,
the hard mask layer includes a plurality of layers of which an uppermost layer has a higher density than the other layers, and the method comprises forming the uppermost layer by an ALD method or a CVD method or forming the uppermost layer with plasma.
